(19) United States
(12) Patent Application Publication
(10) Pub. No.: US 2025/0017094 A1
(43) Pub. Date: Jan. 9, 2025

(54) PROCESSING DEVICE AND METHOD OF MANUFACTURING DISPLAY DEVICE

(71) Applicant: Japan Display Inc., Tokyo (JP)

(72) Inventor: Tatsuya IDE, Tokyo (JP)

(73) Assignee: Japan Display Inc., Tokyo (JP)

(21) Appl. No.: 18/764,420

(22) Filed: Jul. 5, 2024

(30) Foreign Application Priority Data
Jul. 6, 2023 (JP) 2023-111660

(51) Int. Cl. H10K 71/50; H01L 21/67; H10K 59/95

(52) U.S. Cl. CPC H10K 71/50; H01L 21/67121; H10K 59/95

(57) ABSTRACT

According to one embodiment, a processing device includes a stage, a support member including a movable support block, and a vacuum device including a main body and a block, and the processing moves the support block in a first direction to support an end portion region of a display panel and a flexible wiring board disposed outside the stage, causes the end portion area of the display panel and the flexible wiring board to be adsorbed to the main body of the vacuum device, and rotates the main body of the vacuum device and the block of the vacuum device by 180° to bend the display panel in a bend area of the end portion region.

### CROSS-REFERENCE TO RELATED APPLICATION

This application is based upon and claims the benefit of priority from Japanese Patent Application No. 2023-111660, filed Jul. 6, 2023, the entire contents of which are incorporated herein by reference.

### FIELD

Embodiments described herein relate generally to a processing device for a flexible display device.

### BACKGROUND

Flat panel displays such as of organic electroluminescence (EL) display devices include a display panel in which a thin film transistor (TFT) or organic light-emitting diode (OLED) is formed on a substrate. For the base materials for such display panels, glass substrates have conventionally been used, but in recent years, flexible displays that can be bent is being developed, which apply resin films or the like as the base material.

### BRIEF DESCRIPTION OF THE DRAWINGS

FIG. 1 is an overall perspective view of a display device of an embodiment.

FIG. 2 is a cross-sectional view schematically showing an example of a configuration of the display device.

FIG. 3 is a diagram schematically showing a configuration of a processing device for bending flexible circuit boards.

FIG. 4 is a plan view showing the display device and the processing device.

FIG. 5 is a cross-sectional view showing the display device and the processing device.

FIG. 6 is another plan view showing the display device and the processing device.

FIG. 7 is another cross-sectional view showing the display device and the processing device.

FIG. 8 is still another plan view showing the display device and the processing device.

FIG. 9 is still another cross-sectional view showing the display device and the processing device.

FIG. 10 is still another plan view showing the display device and the processing device.

FIG. 11 is still another cross-sectional view showing the display device and the processing device.

FIG. 12 is still another plan view showing the display device and the processing device.

FIG. 13 is still another cross-sectional view showing the display device and the processing device.

FIG. 14 is still another plan view showing the display device and the processing device.

FIG. 15 is still another cross-sectional view showing the display device and the processing device.

FIG. 16 is a partial plan view schematically showing an example of the configuration of the display panel.

FIG. 17 is a cross-sectional view of the display panel taken along line A1-A2 shown in FIG. 16.

### DETAILED DESCRIPTION

In general, according to one embodiment, a processing device comprises
a stage;
a support member including a movable support block; and
a vacuum device including a main body and a block,
the processing device being configured to execute:
holding a display area of a flexible display panel on the stage and disposing an end portion area of the display panel and a flexible wiring board outside the stage, wherein the display panel includes the display area and the end portion area provided thereon, and comprises a flexible base, and the flexible wiring board is connected to a connection portion provided in the end portion area;
disposing the support member adjacent to the stage and the display panel;
moving the support block in a first direction to support the end portion region of the display panel and the flexible wiring board disposed outside the stage;
moving the vacuum device below the support block;
moving the support block in a direction opposite to the first direction to evacuate the support block from the end portion area of the display panel and the flexible circuit board;
raising the vacuum device to cause the end portion area of the display panel and the flexible wiring board to be adsorbed to the main body of the vacuum device;
rotating the main body of the vacuum device and the block of the vacuum device by 180° to bend the display panel in a bend area of the end portion region; and
moving the block of the vacuum device downward to crimp opposing regions of the bend area of the display panel, which oppose each other.

According to another embodiment, a method of manufacturing a display device comprises a flexible display panel including a display area and an end portion area provided thereon, and comprising a flexible base, and the flexible wiring board being connected to a connection portion provided in the end portion area,
the method comprising:
holding the display area of the display panel on the stage and disposing the end portion area of the display panel and the flexible wiring board outside the stage;
disposing a support member including a movable support block adjacent to the stage and the display panel;
moving the support block in a first direction to support the end portion region of the display panel and the flexible wiring board disposed outside the stage;
moving a vacuum device including a main body and a block below the support block;
moving the support block in a direction opposite to the first direction to evacuate the support block from the end portion area of the display panel and the flexible circuit board;
raising the vacuum device to cause the end portion area of the display panel and the flexible wiring board to be adsorbed to the main body of the vacuum device;
rotating the main body of the vacuum device and the block of the vacuum device by 180° to bend the display panel in a bend area of the end portion region; and
moving the block of the vacuum device downward to crimp opposing regions of the bend area of the display panel, which oppose each other.

An object of this embodiment is to provide a processing device which can improve the production yield of display devices.

Embodiments will be described hereinafter with reference to the accompanying drawings. Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

The embodiments described herein are not general ones, but rather embodiments that illustrate the same or corresponding special technical features of the invention. The following is a detailed description of one embodiment of a processing device and a display device with reference to the drawings.

In this embodiment, a first direction X, a second direction Y and a third direction Z are orthogonal to each other, but may intersect at an angle other than 90°. The direction toward the tip of the arrow in the third direction Z is defined as up or above, and the direction opposite to the direction toward the tip of the arrow in the third direction Z is defined as down or below. Note that the first direction X, the second direction Y and the third direction Z may as well be referred to as an X direction, a Y direction and a Z direction, respectively.

With such expressions as “the second member above the first member” and “the second member below the first member”, the second member may be in contact with the first member or may be located away from the first member. In the latter case, a third member may be interposed between the first member and the second member. On the other hand, with such expressions as “the second member on the first member” and “the second member beneath the first member”, the second member is in contact with the first member.

Further, it is assumed that there is an observation position to observe the processing device and display device on a tip side of the arrow in the third direction Z. Here, viewing from this observation position toward the X-Y plane defined by the first direction X and the second direction Y is referred to as plan view. Viewing a cross-section of the processing device and display device in the X-Z plane defined by the first direction X and the third direction Z or in the Y-Z plane defined by the second direction Y and the third direction Z is referred to as cross-sectional view.

### Embodiment

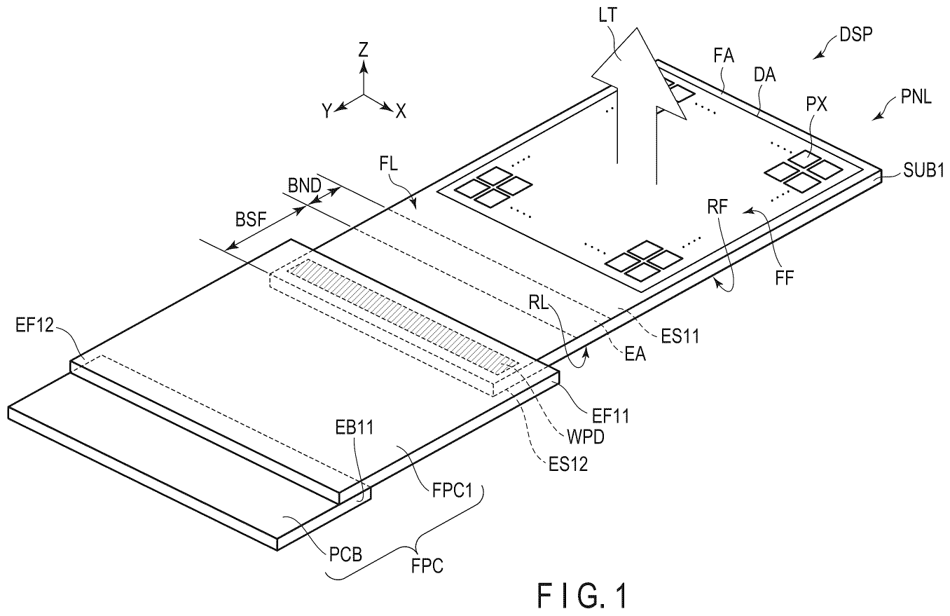

FIG. 1 is an overall perspective view showing a display device of an embodiment. A display device DSP comprises a display area DA and a peripheral area FA provided around the display area DA on a substrate SUB1. The display device DSP includes a plurality of pixels PX arranged in the display area DA. In the display device DSP, light LT from the pixels is emitted upwards.

In FIG. 1, a display panel PNL includes the substrate SUB1, the plurality of pixels PX and the like. The surface of the display panel PNL, which emits the light LT is referred to as a surface FF. The surface on an opposite side to the surface FF in the third direction Z is referred to as a surface RF. The surface FF can be said as a emitting surface, surface, or upper surface, whereas the surface RF as a rear surface or lower surface.

An area EA in an end portion of the substrate SUB1 is disposed on an outer side the display area DA. Of the area EA, the region in the vicinity of the display area DA is referred to as an end portion ES11. An end portion of the area EA, which is spaced apart from the display area DA along the second direction Y is referred to as an end portion ES12. Of the surfaces of the substrate SUB1, a surface that emits the light LT is referred to as a surface FL. A surface on an opposite side to the surface FL is referred to as a surface RL. The surface RL is the same as the surface RF. Note that the area EA may as well be referred to as the end portion area of the display panel PNL.

Connection portions WPD are provided in the area EA on an end portion ES12 side. Wiring lines from the display area DA are extended to the connection portions WPD, respectively. The wiring lines from the display area DA are scanning lines and signal lines from the pixels PX, or wiring lines connected to the scanning lines and the signal lines, respectively.

Between the end portion ES11 and the end portion ES12 of the area EA, a region BND is provided. Between the region BND and the end portion ES12, a region BSF is provided. The region BND is a bend region, and the region BSF is a region to be turned upside down when bent. The region BND and region BSF will be described in detail later.

In the connection portion WPD of the area EA, a flexible wiring board FPC1 is provided. The flexible wiring board FPC1 includes a plurality of wiring lines aligned along the first direction X. The wiring lines of the flexible wiring board FPC1 are electrically connected to the connection portions WPD, respectively, by an anisotropic conductive film (ACF). With this configuration, the wiring lines from the display area DA and the wiring lines of the flexible wiring board FPC1 are electrically connected.

An end portion of the end portion of the flexible wiring board FPC1, which is close proximity to the connection portions WPD is referred to as an end portion EF11. An end portion on an opposite side to the end portion EF11 along the second direction Y is referred to as an end portion EF12. The end portion EF11 is closer to the end portion ES12 of the substrate SUB1 than from the end portion EF12. In other words, the end portion EF11 is located between the end portion EF12 and the end portion ES12.

The end portion EF12 of the flexible wiring board FPC1 is electrically connected to the printed circuit board PCB. The end portion of the printed circuit board PCB, which is connected to the end portion EF12 of the flexible wiring board FPC1, is referred to as an end portion EB11. An end portion on an opposite side to the end portion EB11 along the second direction Y is referred to as an end portion EB12. The end portion EB11 is closer to the end portion ES12 of the substrate SUB1 than from the end portion EB12. In other words, the end portion EB11 is located between the end portion EB12 and the end portion ES12.

Note that the flexible wiring board FPC1 and the printed circuit board PCB may be collectively referred to as flexible wiring boards FPC. Alternatively, the printed circuit board PCB may not be provided, and only the flexible wiring board FPC1 may be provided as a configuration.

The flexible wiring board FPC1 may be provided with a drive element that outputs video signals and drive signals. Signals from the drive element are input respectively to the pixels PX in the display area DA via the flexible wiring board FPC1. Based on the video signals and various types of control signals, the pixels PX emit light.

The substrate SUB1 comprises a flexible base (base BA1, which will be described later) and a plurality of pixels PX. The base may be formed, for example, of a resin film material, more specifically, acrylic, polyimide, polyethylene terephthalate, polyethylene naphthalate, or the like. On the base, a plurality of pixels PX are provided, which include a plurality of switching elements, a plurality of scanning lines, a plurality of signal lines, a plurality of pixel electrodes, a common electrode, a plurality of light emitting layers, and the like. The detailed configuration of the pixels PX and the like will be described later.

Since the substrate SUB1 is flexible, the display panel PNL is a flexible display panel. That is, the display panel PNL is a flexible display.

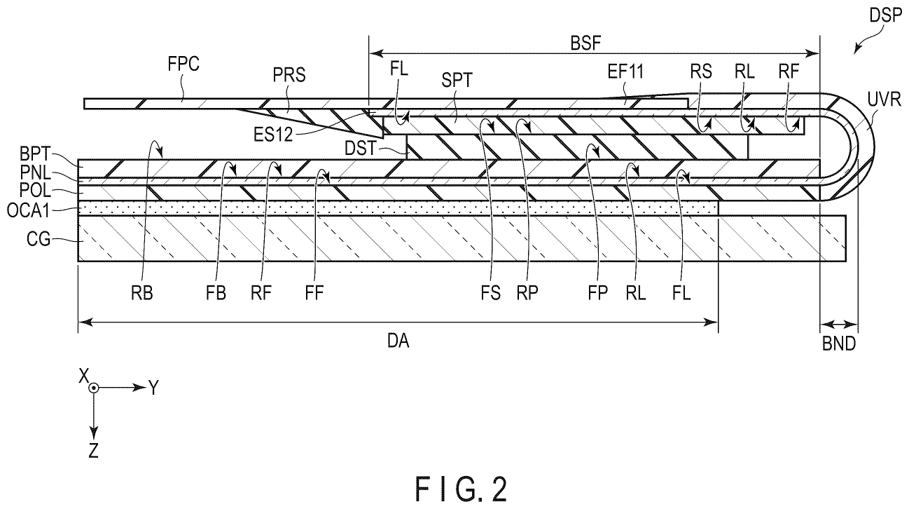

FIG. 2 is a cross-sectional view schematically showing an example of a configuration of a display device. A display device DSP comprises a display panel PNL, a polarizer POL, an optical adhesive OCA1, a cover member CG, a protective member BPT, a protective member UVR, a protective member PRS, a protective member DST, and a flexible circuit board FPC.

In the display device DSP shown in FIG. 2, the display panel PNL is bent in the region BND. By bending the display panel PNL in the region BND, the area EA including the connection portions WPD becomes smaller, thereby making it possible to narrow the frame.

The region BSF of the display panel PNL overlaps a part of the display area DA in an opposite direction of the third direction Z. Between the part of the display area DA and the region BSF, the protective member BPT, protective member DST and protective member SPT are disposed along the direction opposite to the third direction Z.

On the surface FF side of the display panel PNL, a polarizer POL is provided so as to be in contact with the display area DA. The polarizer POL is, for example, a circular polarizer. With the polarizer POL thus provided, for example, reflection of external light in the display area DA can be suppressed.

The polarizer POL is provided with a cover member CG by means of an optical adhesive OCA1. The cover member CG can be, for example, a thin sheet of glass or plastic.

On the surface RF side of the display panel PNL, a protective member BPT is provided. Of the surfaces of the protective member BPT, the surface in contact with the surface RF of the display panel PNL is referred to as a surface FB. Of the surfaces of the protective member BPT, the one on an opposite side to the surface FB is referred to as a surface RB. The protective member DST is provided to be in contact with a part of the surface RB. The protective member BPT mostly overlaps the display area DA of the display panel PNL. More precisely, the protective member BPT overlaps a part of the display area DA and the area EA.

Of the surfaces of the protective member DST, the surface in contact with the surface RB of the protective member BPT is referred to as a surface FP. Of the surfaces of the protective member DST, the one on an opposite side to the surface FP is referred to as a surface RP. The protective member SPT is provided so as to be in contact with the surface RP. The protective member SPT overlaps the region BSF.

Of the surfaces of the protective member SPT, the surface in contact with the surface RP of the protective member DST is referred to as a surface FS. Of the surfaces of the protective member SPT, the one on an opposite side to the surface FS is referred to as a surface RS. The surface RS is in contact with the surface RF (the surface RL of the substrate SUB1) of the region BSF of the display panel PNL.

The protective member BPT and the protective member SPT can be made of a plate-shaped resin material, for example, a plate-shaped polyethylene terephthalate (PET). The protective member BPT and protective member SPT are attached to the surface RF of the display panel PNL so as to oppose each other along the third direction Z while interposing the protective member DST therebetween. With this configuration, they have the function of protecting the display panel PNL.

The protective member DST is a member comprising adhesive layers on its surface and rear surface, respectively, that is, for example, a double-sided tape. The protective member DST adheres the protective member SPT and the protective member BPT all together. Further, it is more preferable for the protective member DST to be a resin material having cushioning properties. The protective member DST has the function of keeping the distance between the bent parts of the display panels PNL to a certain degree or more. With this configuration, even when pressure is applied to the display panel PNL in the thickness direction (third direction Z), the curvature of the region BND is kept within a tolerable range.

The protective member UVR is provided in the region BND of the display panel PNL so as to be in contact with the surface FL. The protective member UVR has the function of protecting the bendable region BND of the display panel PNL. The protective member UVR is provided so as to be in contact with the surface FL of the display panel PNL over between the end portion of the polarizer POL and the end portion EF11 of the flexible circuit board FPC.

The protective member UVR can be, for example, made of a light-curing resin material. The protective member UVR is provided so that there is no gap with the polarizer POL. When a gap exists between the polarizer POL and the protective member UVR, the display panel PNL will break from the gap in the process of bending the display panel PNL, and the wiring lines of the display panel PNL will be disconnected.

The protective member PRS is provided in the vicinity of the end portion ES12 of the display panel PNL, so as to be in contact with the end portion ES12, the protective member SPT, and the flexible wiring board FPC.

The protective member PRS can be, for example, a resin material. The protective member PRS has the function of protecting the end portion ES12 of the display panel PNL.

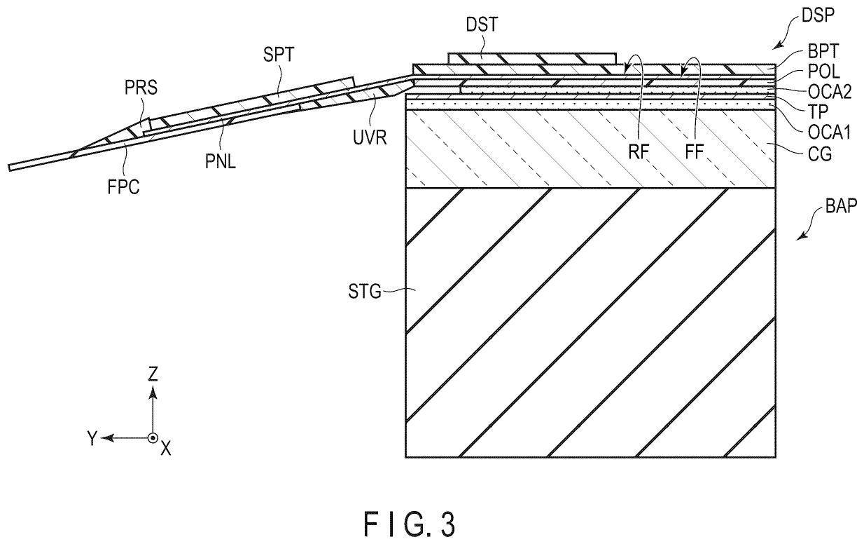

FIG. 3 is a diagram schematically showing a processing device for bending flexible wiring boards. The processing device BAP includes a stage STG. In the process of bending the flexible wiring board FPC1 of the display device DSP, the display area DA of the display panel PNL (the substrate SUB1) is placed on the stage STG, and the area EA of the end portion, the flexible wiring board FPC1, and the printed circuit board PCB are placed so as to protrude from the stage STG.

As shown in FIG. 3, after the display panel PNL and the like are placed, a unit equipped with suction and crimping members moves to the stage STG side so as to suction, and rotates to bend the region BND of the display panel PNL. In order for this unit to be able to make contact, no holding mechanism is provided on the part disposed to protrude from the stage STG. Therefore, the area EA of the display panel PNL and the flexible wiring board FPC1 are placed to protrude out from the stage STG hang down by its own weight, which may cause a damage to the wiring lines in the display panel PNL and the flexible wiring board FPC1. If such wiring lines are disconnected, the display device DSP may become defective, resulting in a lower yield rate.

The display device DSP is placed on the stage STG in an upside-down state so that the light-emitting surface FF is down. The display device DSP shown in FIG. 3 is provided with a polarizer POL so as to be in contact with the display panel PNL. To the polarizer POL, a touch panel TP is adhered by means of an optical adhesive OCA1. Further, on the touch panel TP, the cover member CG is provided by means of an optical adhesive OCA2.

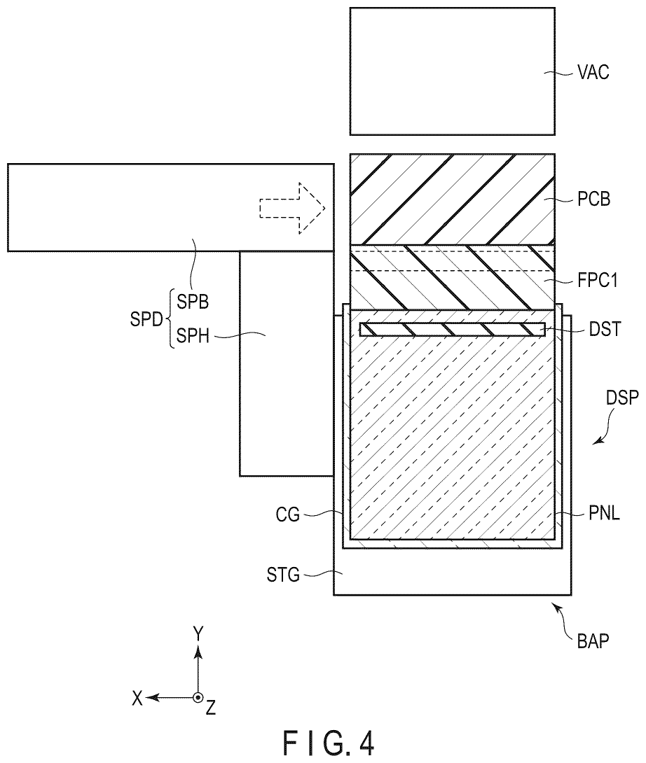

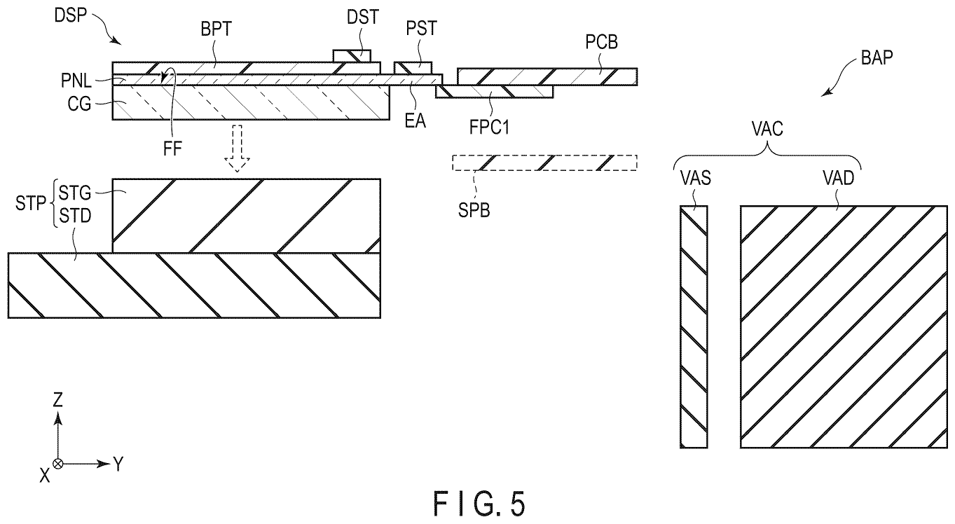

The process of bending the display panel PNL by the processing device BAP will be explained with reference to FIGS. 4 to 15. FIGS. 4, 6, 8, 10, 12, and 14 are plan views of the display device and processing device. FIGS. 5, 7, 9, 11, 13, and 15 are cross-sectional views of the display device and processing device.

As shown in FIGS. 4 and 5, a processing device BAP comprises a support member SPD and a vacuum device VAC, in addition to the stage STG. The support member SPD comprises a support stand SPH and a support block SPB. The stage STG is disposed on the stage stand STD. The stage STG and the stage stand STD are together referred to as a stage device STP.

The support stand SPH of the support member SPD is provided adjacent to the stage STG. The support block SPB moves along a direction opposite to the first direction X. The support block SPB is located below but not directly below the area EA of the end portion, the flexible circuit board FPC1, and the printed circuit board PCB. The support block SPB is disposed to be spaced apart from the area EA of the end portion, the flexible circuit board FPC1, and the printed circuit board PCB in plan view.

The vacuum device VAC comprises a main body VAD and a block VAS. In FIGS. 4 and 5, the vacuum device VAC is spaced apart from the display device DSP and the stage device STP.

First, as in the case shown in FIG. 3, the display area DA of the display panel PNL is held on the stage STG. The area EA of the end portion, the flexible wiring board FPC1, and the printed circuit board PCB are placed to protrude out from the stage STG.

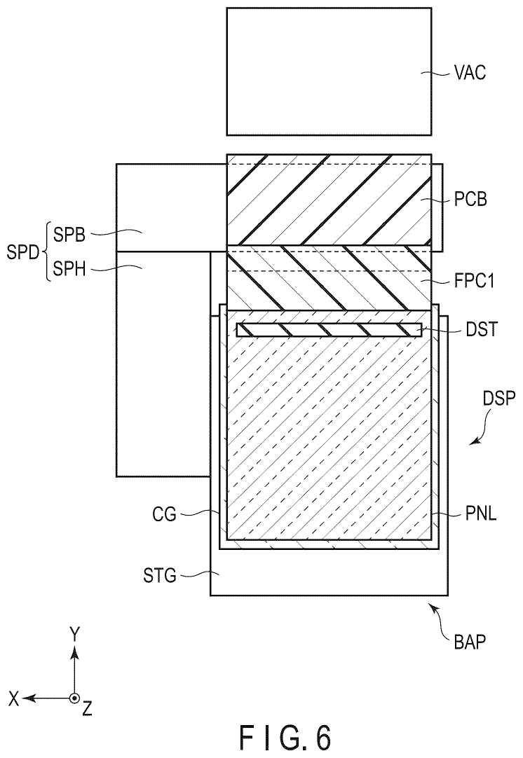

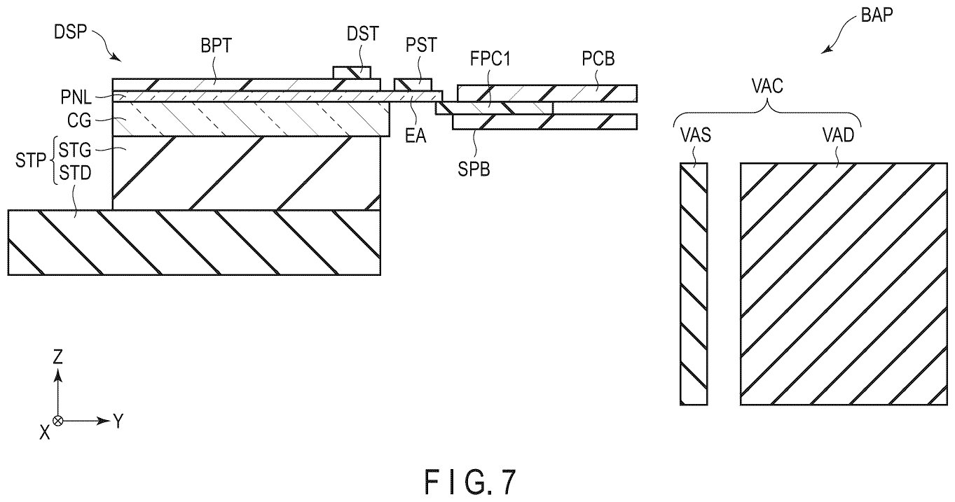

Next, the support block SPB slides along a direction opposite to the first direction X (see FIGS. 6 and 7). The support block SPB moves below the area EA, the flexible circuit board FPC1, and the printed circuit board PCB to support the area EA, the flexible circuit board FPC1, and the printed circuit board PCB.

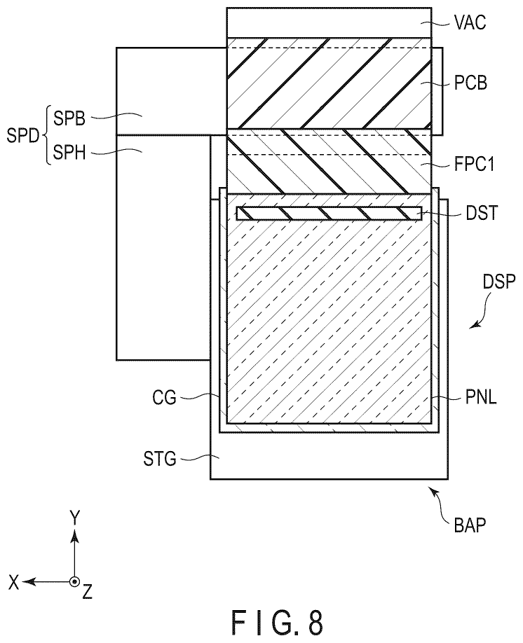

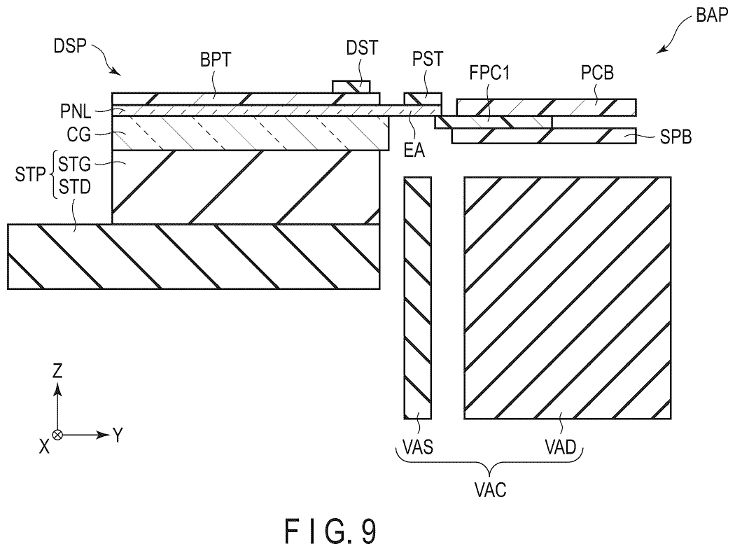

Next, the vacuum device VAC moves along a direction opposite to the second direction Y. The vacuum device VAC is disposed below the support block SPB (see FIGS. 8 and 9).

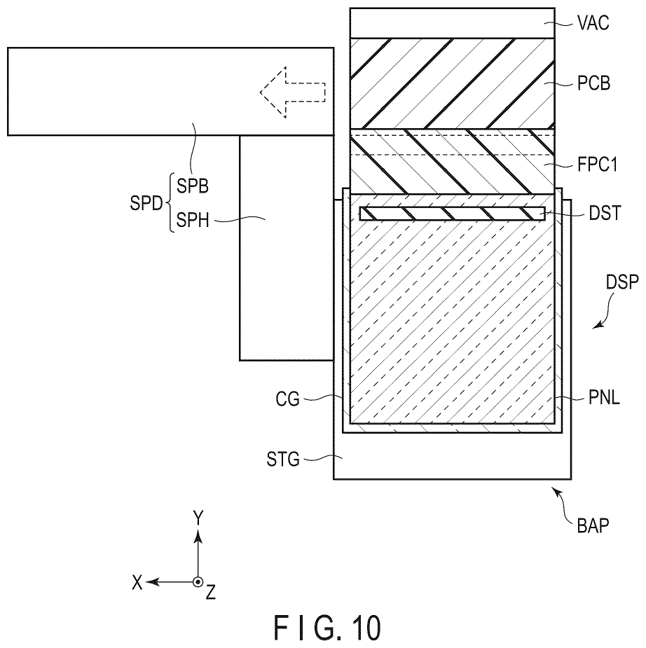

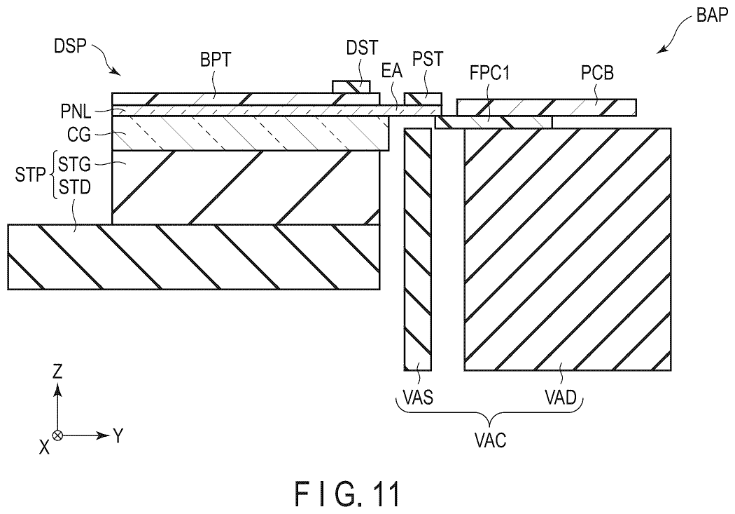

After the vacuum device VAC moves to below the support block SPB, the support block SPB, which has been located below the display panel PNL, is evacuated. Thus, only the vacuum device VAC is placed below the display panel PNL. Next, the vacuum device VAC moves along the third direction Z, that is, rises so as to adsorb the area EA, the flexible circuit board FPC1, and the printed circuit board PCB (see FIGS. 10 and 11).

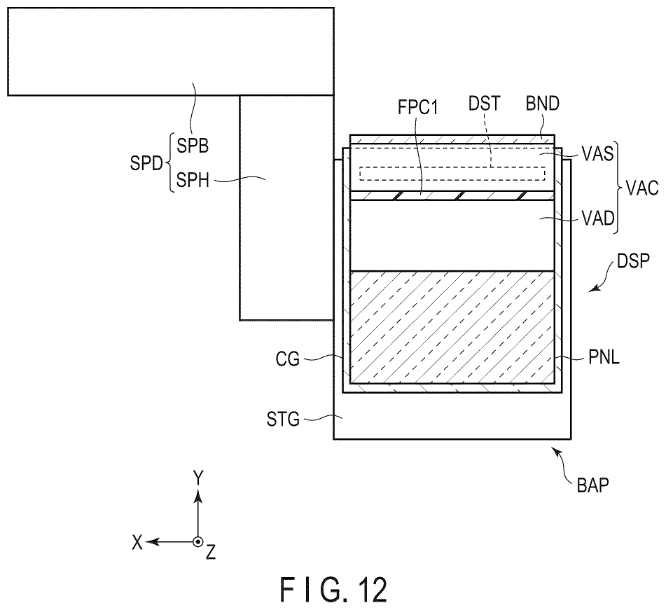

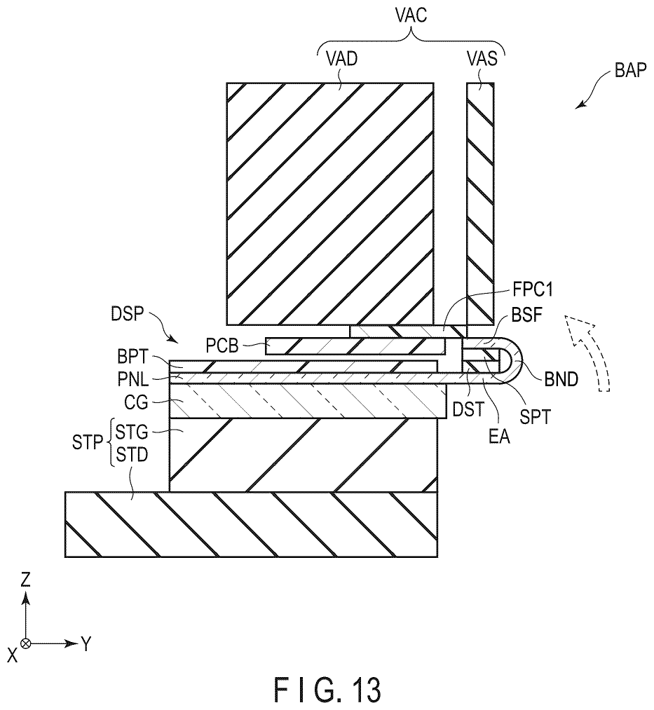

Next, the vacuum device VAC is rotated by 1800 with respect to the X-Y plane (see FIGS. 12 and 13). In other words, the vacuum device VAC is rotated so as to be upside down. The main body VAD of the vacuum device VAC adsorbs the area EA, the flexible circuit board FPC1, and the printed circuit board PCB. With this operation, the display panel PNL is bent in the region BND. The region BSF in the area EA, the flexible wiring board FPC1, and the printed circuit board PCB are disposed upside down. The region BND may as well be referred to as a bend region, and the region BSF as an inverted region.

The block VAS of the vacuum device VAC is placed above the region BSF, the protective member DST, and the protective member SPT, so as to be spaced apart from the protective member DST and the protective member SPT. Note that in FIG. 13, for drafting convenience, the lengths of the protective member DST and the protective member SPT along the direction parallel to the second direction Y are approximately the same as each other. But, as shown in FIG. 2, the length of the protective member SPT along the direction parallel to the second direction Y is greater than that of the protective member DST along the direction parallel to the second direction Y.

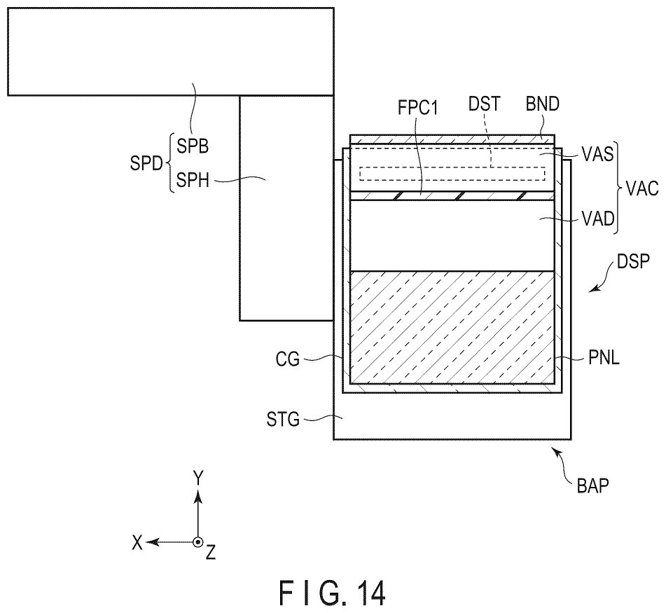

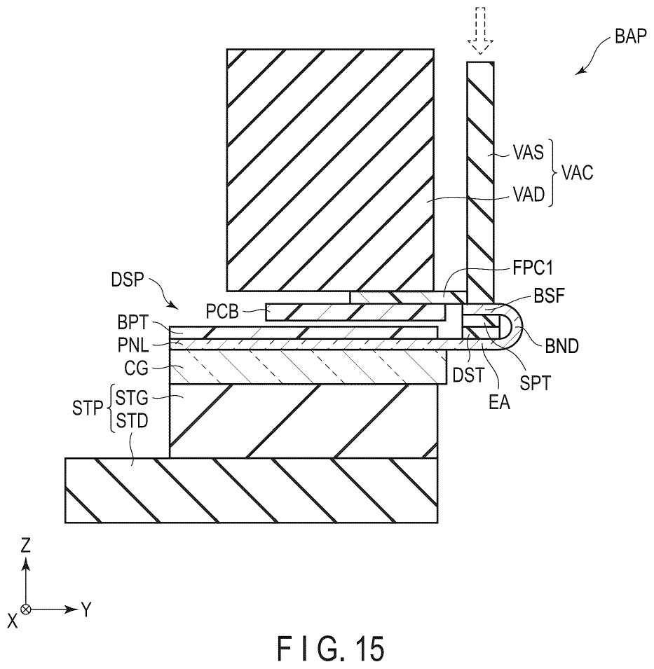

Next, the block VAS of the vacuum device VAC moves downward (in a direction opposite to the third direction Z) and crimps the regions of the bent display panel PNL, which oppose each other along the third direction Z to each other. More specifically, the block VAS moves downward to crimp the region BSF, protective member DST, and protective member SPT of the display panel PNL (see FIGS. 14 and 15). In more detail, as shown in FIG. 2, the protective member BPT overlapping the display area DA of the display panel PNL, the protective member SPT overlapping the region BSF, and the protective member DST disposed between the protective member BPT and the protective member SPT are crimped so that the display area DA and the region BSF are crimped at a predetermined interval. The protective member BPT and the protective member SPT may as well be referred to as the first protective member and the second protective member, respectively.

Here, the crimping of the region BSF, the protective member DST, and the protective member SPT of the display panel PNL may be so-called temporary fixing. After the process described in FIGS. 14 and 15, the display panel PNL, the protective member DST, and the protective member SPT may be fixed using some other crimping device.

In this embodiment, the support member SPD including the support stand SPH and support block SPB is prepared apart from the stage STG. The support block SPB of the support member SPD can support the display panel PNL, the flexible wiring board FPC1, and the printed circuit board PCB. With this configuration, it is possible to prevent the display panel PNL1 and flexible wiring board FPC1 from bending under its own weight. Thus, the disconnection of the wiring lines in the display panel PNL1 and flexible wiring board FPC1 can be prevented.

Here, the pixels PX of the display panel PNL will now be explained in more detail.

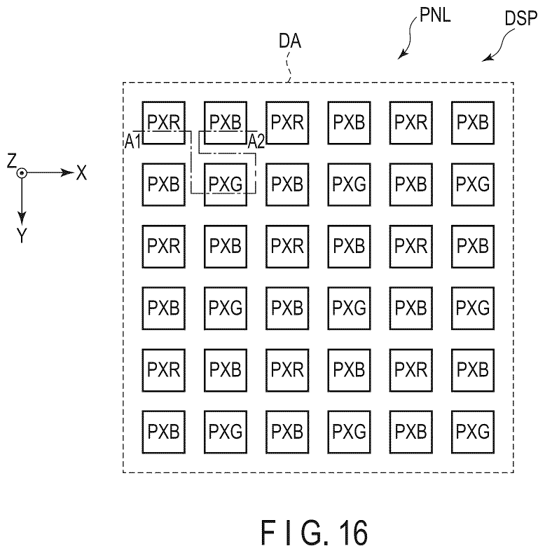

FIG. 16 is a partial plan view schematically showing an example of a configuration of the display device. The plurality of pixels PX include pixels PXR which emit red color, pixels PXG which emit green color, and pixels PXB which emit blue color. The pixels PXR, pixels PXG, and pixels PXB may as well be referred to as the first pixels, second pixels, and third pixels, respectively. The pixels PXR are each disposed to be adjacent to a respective pixel PXB along the first direction X and the second direction Y. The pixels PXG are each disposed to be adjacent to a respective pixel PXB along the first direction X and the second direction Y. The pixels PXB are each disposed adjacent to a respective pixel PXR along the first direction and adjacent to a respective pixel PXG along the second direction Y.

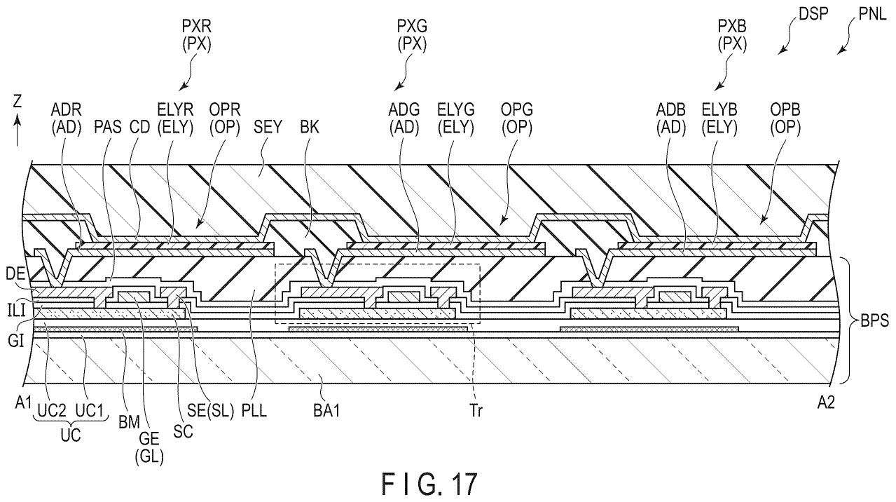

FIG. 17 is a cross-sectional view showing the display device taken along line A1-A2 in FIG. 16.

The base BA1 is formed of, for example, a resin material as described above. Usable examples of the resin material are acrylic, polyimide, polyethylene terephthalate, polyethylene naphthalate and the like, and may be formed from a single layer or a stacked body of multiple layers of any of these materials.

On the base BA1, an insulating layer UC1 is provided. The insulating layer UC1 is formed, for example, from a single layer of or a stacked body of one or both of a silicon oxide film and a silicon nitride film.

On the insulating layer UC1, a light-shielding layer BM may be provided so as to overlap a transistor Tr. The light-shielding layer BM suppresses changes in transistor characteristics, which may be caused by light penetration or the like, from the rear surface of the channel of the transistor Tr. When the light-shielding layer BM is formed from a conductive layer, it is also possible to impart a back-gate effect to the transistor Tr by applying a predetermined potential.

An insulating layer UC2 is provided to cover the insulating layer UC1 and the light-shielding layer BM. A material similar to that of the insulating layer UC1 can be used for the insulating layer UC2 as well. Note that the insulating layer UC2 may be formed of a material different from that of the insulating layer UC1. For example, silicon oxide can be used for the insulating layer UC1, whereas silicon nitride for insulating layer UC2. The insulating layers UC1 and UC2 are collectively referred to an insulating layer UC.

The transistor Tr is provided on the insulating layer UC. The transistor Tr includes a semiconductor layer SC, an insulating layer GI, a gate electrode GE (scanning line), an insulating layer ILI, a source electrode SE (signal line) and a drain electrode DE. The transistor Tr is a thin-film transistor (TFT).

Amorphous silicon, polysilicon, or oxide semiconductor is used as the semiconductor layer SC.

As the insulating layer GI, for example, silicon oxide or silicon nitride is provided to form a single layer or a stacked body of layers of these.

For example, a molybdenum-tungsten alloy (MoW) is used as the gate electrode GE. The gate electrode GE may as well be formed to be integrated with the scanning line GL as on body.

The insulating layer ILI is provided to cover the semiconductor layer SC and the gate electrode GE. The insulating layer ILI is formed, for example, from a single layer of a silicon oxide layer or silicon nitride layer or a stacked body of layers of these.

On the insulating layer ILI, the source electrode SE and the drain electrode DE are provided. The source electrode SE and the drain electrode DE are connected to the source region and drain region of the semiconductor layer SC, respectively, via contact holes formed in the insulating layer ILI and the insulating layer GI, respectively. The source electrode SE may as well be formed to be integrated with the signal line as one body.

An insulating layer PAS is provided to cover the source electrode SE, the drain electrode DE, and the insulating layer ILI. An insulating layer PLL is provided to cover the insulating layer PAS.

The insulating layer PAS is formed from an inorganic insulating material. As the inorganic insulating material, for example, a single layer of silicon oxide or silicon nitride or a stacked body layers of these can be used. The insulating layer PLL is formed from an organic insulating material. Examples of the organic insulating material include photosensitive acrylic, polyimide, and other organic materials. With the insulating layer PLL thus provided, steps caused by the transistor Tr can be planarized.

An anode AD is provided on the insulating layer PLL. The anode AD is connected to the drain electrode DE via contact holes formed in the insulating layer PAS and PLL. The anode provided in each pixel PXR is referred to as an anode ADR, the anode provided in each pixel PXB is referred to as an anode ADB, and the anode provided in each pixel PXG is referred to as an anode ADG. When there is no need to distinguish between the anode ADR, anode ADG, and anode ADB, they are simply referred to as anodes AD.

The anodes AD, for example, should be formed from a stacked body of a reflective electrode and a transparent electrode. The reflective electrode is formed from a conductive material having high reflectivity, that is, for example, silver (Ag) or aluminum (Al). The transparent electrode is formed using indium tin oxide (ITO) and indium zinc oxide (IZO), for example.

In this embodiment, the configuration from the base BA1 to the insulating layer PLL is referred to as a backplane BPS.

A bank BK (which may as well be referred to as a projecting portion or rib) is provided between each adjacent pair of anodes AD. As the material of the bank BK, an organic material similar to the material of the insulating layer PLL is used. The bank BK is opened to expose a part of each anode AD.

Here, the aperture formed in each pixel PXR is referred to as an apertures OPR, the aperture formed in each pixel PXB is referred to as an aperture OPB, and the aperture formed in each pixel PXG is referred to as an aperture OPG. When there is no need to distinguish between the aperture OPR, aperture OPB, and aperture OPG, they are simply referred to as apertures OP.

Note that it is preferable that an end portion of each aperture OP should be gently tapered in cross-sectional view. When the end portion of the aperture OP has a steep shape, coverage error may occur in an organic EL layer ELY, which is formed in a later step.

The organic EL layer ELY is provided between each adjacent portions of the bank BK so as to overlap the respective anode AD. The organic EL layer ELY includes a hole injection layer, a hole transport layer, an emission layer, an electron transport layer, and an electron injection layer. The organic EL layer ELY may further include an electron blocking layer, a hole blocking layer, if necessary.

Here, the organic EL layer provided in each pixel PXR is referred to as an organic EL layer ELYR, the organic EL layer provided in each pixel PXB is referred to as an organic EL layer ELYB, and the organic EL layer provided in each pixel PXG is referred to as an organic EL layer ELYG. When there is no need to distinguish between the organic EL layer ELYR, organic EL layer ELYG, and organic EL layer ELYB, they are simply referred to organic EL layers ELY.

A cathode CD is provided on the organic EL layer ELY. The cathode CD is formed, for example, from a magnesium-silver alloy (MgAg) film, a single-layered film of silver (Ag), or a staked layered film of silver (Ag) and a transparent conductive material. For the transparent conductive material, indium tin oxide (ITO) and indium zinc oxide (IZO), for example, can be used.

An insulating layer SEY is provided to cover the cathode CD. The insulating layer SEY has the function of preventing moisture from entering the organic EL layer ELY from the outside. As the insulating layer SEY, a type with high gas barrier property is preferable. As the insulating layer SEY, for example, an insulating layer formed by interposing an organic insulating layer between two inorganic insulating layers containing nitrogen, can be used. Examples of the material for the organic insulating layer include acrylic resin, epoxy resin, polyimide resin and the like. Examples of the material of the inorganic insulating layer containing nitrogen include silicon nitride, aluminum nitride and the like.

The light emission generated in the organic EL layer ELY is extracted upward via the cathode CD. In other words, the display device DSP (display panel PNL) of this embodiment has a top emission structure.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A processing device comprising:
a stage;
a support member including a movable support block; and
a vacuum device including a main body and a block,
the processing device being configured to execute:
holding a display area of a flexible display panel on the stage and disposing an end portion area of the display panel and a flexible wiring board outside the stage, wherein the display panel includes the display area and the end portion area provided thereon, and comprises a flexible base, and the flexible wiring board is connected to a connection portion provided in the end portion area;
disposing the support member adjacent to the stage and the display panel;
moving the support block in a first direction to support the end portion region of the display panel and the flexible wiring board disposed outside the stage;
moving the vacuum device below the support block;
moving the support block in a direction opposite to the first direction to evacuate the support block from the end portion area of the display panel and the flexible circuit board;
raising the vacuum device to cause the end portion area of the display panel and the flexible wiring board to be adsorbed to the main body of the vacuum device;
rotating the main body of the vacuum device and the block of the vacuum device by 180° to bend the display panel in a bend area of the end portion region; and
moving the block of the vacuum device downward to crimp opposing regions of the bend area of the display panel, which oppose each other.

2. The processing device according to claim 1, wherein
the display device further comprises a printed circuit board that is connected to the flexible circuit board.

3. The processing device according to claim 1, wherein
the substrate is formed of a resin film material of acrylic, polyimide, polyethylene terephthalate, or polyethylene naphthalate.

4. The processing device according to claim 1, wherein
the display device further comprises a double-sided tape disposed between the opposing regions.

5. The processing device according to claim 1, wherein
the display device further comprises a light-curing resin material on the bend area.

6. The processing device according to claim 1, wherein:
the display device further comprises:
a first protective member overlapping the display area;
a second protective member overlapping an inverted region of the end portion region, which different from the bend area,
a double-sided tape disposed between the first protective member and the second protective member.

7. A method of manufacturing a display device comprising a flexible display panel including a display area and an end portion area provided thereon, and comprising a flexible base, and the flexible wiring board being connected to a connection portion provided in the end portion area,
the method comprising:
holding the display area of the display panel on the stage and disposing the end portion area of the display panel and the flexible wiring board outside the stage;
disposing a support member including a movable support block adjacent to the stage and the display panel;
moving the support block in a first direction to support the end portion region of the display panel and the flexible wiring board disposed outside the stage;
moving a vacuum device including a main body and a block below the support block;
moving the support block in a direction opposite to the first direction to evacuate the support block from the end portion area of the display panel and the flexible circuit board;
raising the vacuum device to cause the end portion area of the display panel and the flexible wiring board to be adsorbed to the main body of the vacuum device;
rotating the main body of the vacuum device and the block of the vacuum device by 180° to bend the display panel in a bend area of the end portion region; and
moving the block of the vacuum device downward to crimp opposing regions of the bend area of the display panel, which oppose each other.

8. The method according to claim 7, wherein
the display device further comprises a printed circuit board that is connected to the flexible circuit board.

9. The method according to claim 7, wherein
the substrate is formed of a resin film material of acrylic, polyimide, polyethylene terephthalate, or polyethylene naphthalate.

10. The method according to claim 7, wherein
the display device further comprises a double-sided tape disposed between the opposing regions.

11. The method according to claim 7, wherein
the display device further comprises a light-curing resin material on the bend area.

12. The method according to claim 7, wherein
the display device further comprises:
a first protective member overlapping the display area;
a second protective member overlapping an inverted region of the end portion region, which different from the bend area,
a double-sided tape disposed between the first protective member and the second protective member.
